(19) United States
(12) Patent Application Publication
(10) Pub. No.: US 2003/0016029 A1
(43) Pub. Date: Jan. 23, 2003

(54) Soil moisture measuring system for a mobile agricultural device

(76) Inventors: Ronald T. Schuler, Madison, WI (US); Birl Lowery, Madison, WI (US); Robert L. Silha, Madison, WI (US)

Correspondence Address: Andrew S. McConnell, Boyle, Fredrickson, Newholm, Stein & Gratz, S.C., Suite 1030, 250 E. Wisconsin Avenue, Milwaukee, WI, 53202, US

(21) Appl. No.: 09/908,386

(22) Filed: Jul. 18, 2001

(51) Int. Cl. G01R 27/04; G01R 27/32

(52) U.S. Cl. 324/643

(57) ABSTRACT

A soil moisture measurement system is incorporated in an agricultural implement, for measuring soil moisture during operation of the implement. The soil moisture measurement system includes a sensor or input unit mounted to a subsoil portion of the implement, e.g. to the shank portion of a tillage implement. The soil moisture measurement system may be in the form of a time domain reflectivity (TDR) system. The operator can adjust the depth of the soil-working portion of the implement to attain a desired degree of soil penetration according to soil moisture conditions for seeds to be planted within the soil. Depth adjustment can be accomplished manually by the operator, or automatically by virtue of a depth control unit interconnected with the implement.

This invention was made with United States government support awarded by the following agencies: USDA 00-33610-8886. The United States has certain rights in this invention.

### BACKGROUND AND SUMMARY OF THE INVENTION

This invention relates to a soil moisture measuring system, and more particularly to a soil moisture measuring system for use in connection with an agricultural device implement adapted to be moved through the soil.

In agricultural crop production, crop yields are maximized when optimal seed germination conditions are attained. To provide good germination and emergence, the seed must be placed at the proper depth in the soil in such a manner so as to provide good seed to soil contact. Moisture in the soil provides rapid germination, and contact between the soil and seed is important for the transfer of water from the soil to the seed. To obtain optimal seed to soil contact, the soil must be properly tilled before the seed is planted. Without proper tillage of the soil, the planting equipment will be unable to create optimal seed to soil contact.

It is well known that various characteristics of an agricultural field vary from location to location within the field. Such characteristics include plant nutrients, soil texture, topography, soil moisture and soil strength. In view of this, it is known that crop yield and quality within a field will vary if the variable field characteristics are not taken into account when the field is tilled and planted. Precision agriculture, also known as site specific crop management, has been developed to allow a crop producer to assess and manage variability within a crop production field. By applying the correct practice or crop input in the correct place at the correct time, the crop producer will enhance profitability by improving crop yield and quality, and will also reduce risks to the environment.

In addition, it has been found that yield variability patterns are not constant from year to year. This is primarily due to changes in soil moisture distribution between growing seasons. Yield variability is related to soil texture, moisture and strength, all of which are interrelated, and variations in soil moisture from year to year will have a significant effect on crop yields for the same field.

In a field with varying soil moisture characteristics, proper tillage can be maintained by adjusting the tillage equipment to match the changing field conditions. One example is to adjust the depth of the tillage equipment as soil moisture conditions change since, if no adjustment is made, the depth will be less in lower moisture conditions than higher moisture conditions, for the same soil type.

The same considerations apply for equipment which plants seeds in the soil, since different soil moisture conditions have an effect on planting depth. Further, the seed must be placed in moist soil if there is a change in moisture conditions according to the recommended planting depth for a particular crop. For example, in a seed having a recommended planting depth of 0.75 to 3.00 inches, the soil in the shallow end of the range may be too dry for rapid germination, yet the soil at the lower depth of the range may have ideal moisture conditions for rapid germination. Therefore, the seed should be placed at a greater depth to ensure rapid germination and emergence.

In the past, it has been known to measure soil moisture at various locations within the field, to ascertain the general moisture conditions of the field. Again, this approach is limited in that soil moisture characteristics are calculated in a general manner, and may vary greatly from the soil moisture characteristics at any specific location within the field.

It can thus be appreciated that, in order to produce optimal conditions to maximize crop yield, it is desirable to ascertain soil moisture characteristics at specific locations within the field, in order to ensure that tillage depths are proper and that seeds are planted in soil having moisture characteristics which provide optimal germination and rapid growth conditions.

It is an object of the present invention to provide a soil moisture measuring system for providing specific soil moisture measurements throughout a crop production field. It is a further object of the invention to provide a system for measuring soil moisture which is adapted for use in combination with a device, such as a tillage implement or a planter, which is adapted to be moved through the field to work the soil. It is a further object of the invention to provide a soil moisture measurement system which requires little modification to existing agricultural equipment, yet which is capable of providing accurate soil moisture measurements. Yet another object of the invention is to provide a system for altering the depth of a soil penetrating member associated with a mobile agricultural device, in response to soil moisture measurements taken as the soil penetrating member is moved through the soil.

The present invention contemplates a soil moisture measuring system and method for use in combination with a mobile agricultural device having a soil penetrating member adapted to be moved through the soil during movement of the mobile agricultural device. Representatively, the agricultural device may be in the form of a tillage implement adapted to be towed behind a tractor or the like. The soil moisture measuring system includes a soil moisture input arrangement associated with a soil penetrating portion of the soil penetrating member. The soil moisture input arrangement is adapted to be positioned beneath the soil during movement of the soil penetrating portion of the soil penetrating member. The soil moisture measuring system further includes a processor interconnected with the soil moisture input arrangement, which receives inputs therefrom and which provides an output indicative of soil moisture as the soil penetrating member is moved through the soil.

In one form, the soil moisture input arrangement includes spaced apart electrodes which are mounted to the soil penetrating portion of the soil penetrating member, and the electrodes are connected to the processor for providing inputs to the processor indicative of soil moisture. In one form, soil moisture measurements can be obtained using a time domain reflectivity (TDR) system. The soil penetrating portion of the soil penetrating member may be formed with a recess within which the electrodes are positioned, and the electrodes are configured so as to establish contact with the soil as the soil penetrating member portion of the soil penetrating member is moved through the soil.

The soil moisture measurement information can be provided in a visual form to the operator of the tractor, who can utilize the soil moisture information to adjust the depth of the soil penetrating member in the soil. The soil moisture information can also be gathered and plotted according to the location within the field, to generate a site specific soil moisture map for the field which can be used when planting the field. The soil moisture measuring system can also be connected to a control arrangement for adjusting the depth of the soil penetrating member on the fly.

Various other features, objects and advantages of the invention will be made apparent from the following description taken together with the drawings.

### BRIEF DESCRIPTION OF THE DRAWINGS

The drawings illustrate the best mode presently contemplated of carrying out the invention.

In the drawings:

FIG. 1 is an isometric view showing a soil moisture measuring system in accordance with the present invention, incorporated into the subsoil portion of the shank of a tillage implement;

FIG. 2 is a schematic view illustrating the components of the soil moisture measuring system of FIG. 1, incorporated into an implement having operator-controlled depth adjustment;

FIG. 3 is a side elevation view of the shank of the tillage implement of FIG. 1, showing a soil moisture input arrangement incorporated into the subsoil shank of the implement;

FIG. 4 is an exploded view similar to FIG. 3, showing the components of the subsoil shank and mounting of the soil moisture input arrangement thereto;

FIG. 5 is a partial section view taken along line 5-5 of FIG. 3;

FIG. 6 is a view similar to FIG. 3, showing an alternative location for the soil moisture input arrangement incorporated into the subsoil shank;

FIG. 7 is a view similar to FIG. 2, showing components incorporated into an automatic depth adjustment system; and

FIG. 8 is a view similar to FIGS. 2 and 6, showing an alternative embodiment incorporating a number of soil moisture input arrangements incorporated into the subsoil shank.

### DETAILED DESCRIPTION OF THE INVENTION

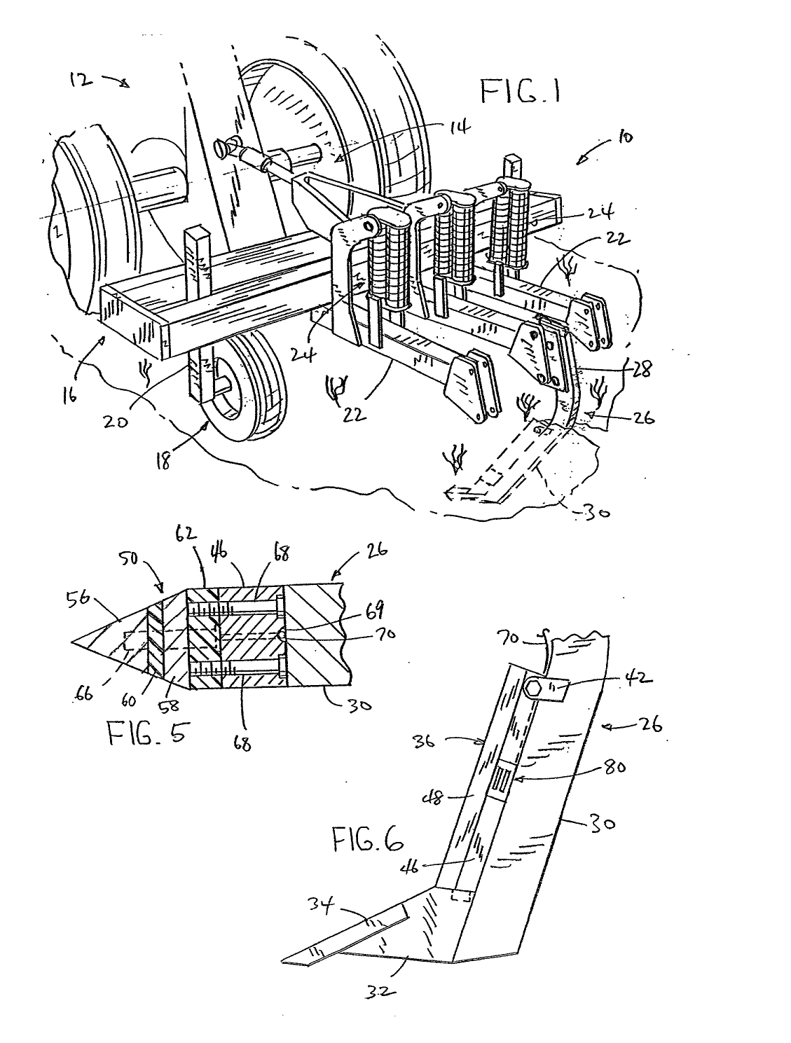

FIG. 1 illustrates a tillage implement 10 mounted to a tow vehicle such as a tractor 12 by means of a conventional hitch mechanism shown representatively at 14. In a manner as is known, tillage implement 10 includes a frame 16 having a set of wheels 18 adapted to engage the ground when hitch mechanism 14 is operated to lower implement 10 into engagement with the ground. Each wheel 18 is rotatably mounted to the lower end of a wheel support member 20 which is mounted to frame 16 by means of a mounting arrangement which provides upward and downward movement of wheel support 20 relative to frame 18. Representatively, a screw-type mechanism may be interposed between frame 16 and each wheel support member 20, which is adapted to be operated by the operator so as to raise and lower wheels 18 relative to frame 16. In this manner, the operator can control the vertical position of frame 16 relative to the ground when implement 10 is lowered so as to engage wheels 18 with the ground. Alternatively, a hydraulic cylinder may be positioned between frame 16 and each wheel support 20, for raising or lowering frame 16 relative to wheel 18.

Frame 16 further supports a series of rearwardly extending arms 22, each of which is mounted to frame 16 by means of a spring-type mounting system 24. The rearward end of each mounting arm 22 is adapted to support a soil-engaging shank member, shown generally at 26. Shank member 26 includes an upper mounting portion 28 and a lower subsoil or soil engaging portion 30. In a manner as is known, soil engaging portion 30 is adapted to be positioned beneath the soil and drawn through the soil upon advancement of tractor 12 through a field, to till the soil prior to planting of crop seeds.

FIG. 1 illustrates a single shank member 26 mounted to one of arms 22. It is understood, however, that normally a shank member such as 26 is mounted to each arm 22 during use of implement 10. Further, while the drawings illustrate only three arms 22, it is understood that implement 10 may have any number of arms and associated shank members, according to the width of frame 16 and the operating characteristics of implement 10.

The general construction of implement 10 as shown and described is known in the prior art. Representatively, an implement such as 10 is available from Case DMI of Goodfield, Ill. under its designation Ecolo-Till 2500 with an MRD shank, although it is understood that other satisfactory implements may be employed.

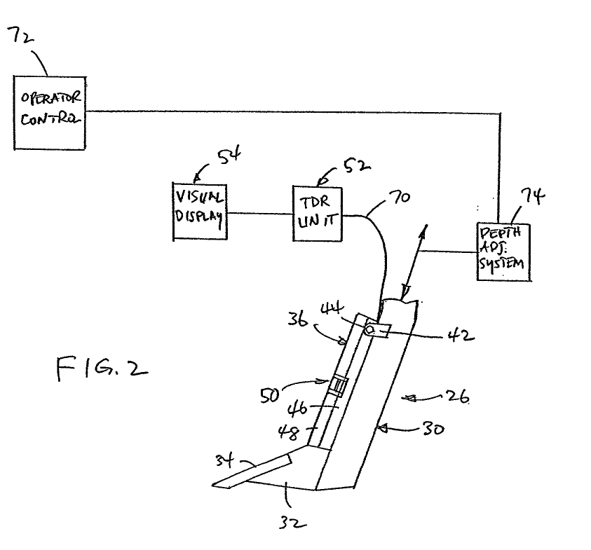

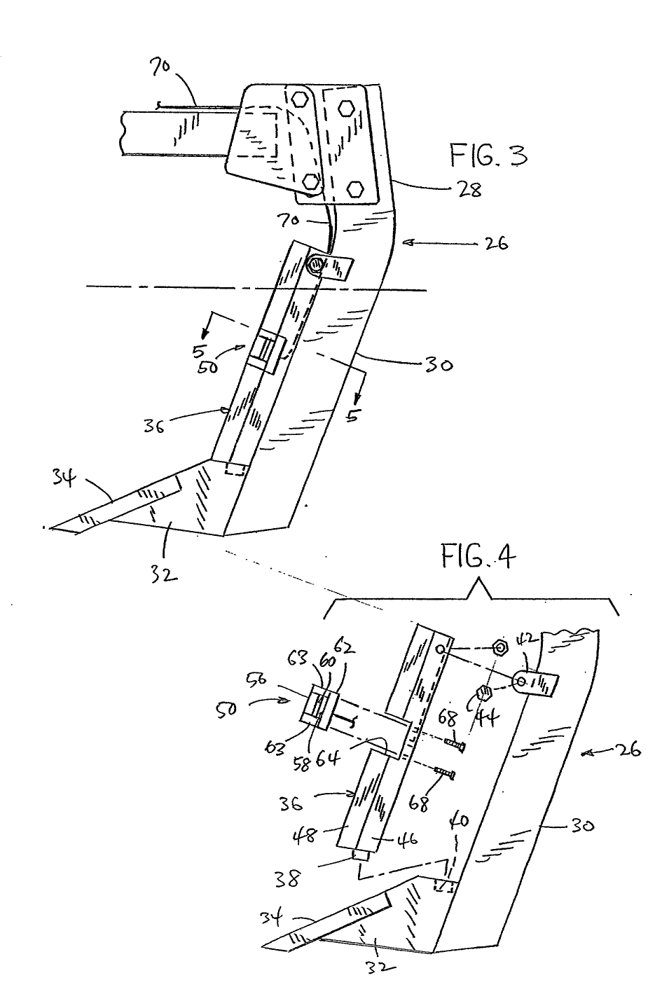

FIG. 3 illustrates the construction of shank member 26 in greater detail. Generally, shank member 26 includes upper mounting portion 28 and soil penetrating portion 30 extending downwardly from upper mounting portion 28. In the embodiment of FIG. 2, soil penetrating portion 30 is in the form of a substantially straight soil penetrating member extending at an angle relative to upper mounting portion 28. In an alternative embodiment, shank member 26 may be a continuous curve between its upper mounting portion and its lower soil-penetrating portion, in a manner as is known.

Shank member 26 further includes a foot 32 mounted to the lower end of soil penetrating portion 30 and extending forwardly therefrom. A tooth 34 is engaged with and supported by foot 32.

Shank member 26 further includes a shin wedge 36 which extends upwardly from the top of foot 32 and is located forwardly of the forward edge of shank member soil penetrating portion 30. Shin wedge 36 is removably engaged with shank member 26. Representatively, shin wedge 36 may have a protrusion 38 (FIG. 4) at its lower end, which is received within a recess 40 formed in the upper edge of foot 32. The upper end of shin wedge 36 is received between a pair of mounting ears 42 which extend forwardly of the forward edge of soil penetrating portion 30. A bolt 44 extends through openings in ears 42 and an aligned passage in the upper end of shin wedge 36, for releasably maintaining shin wedge 36 in engagement with shank member 26 when protrusion 38 at the lower end of shin wedge 36 is received within recess 40. Again, in a manner as is known, shin wedge 36 includes a rear base portion 46 which has a width substantially equal to the width of soil penetrating portion 30 of shank member 26, and an angled front wedge portion 48 terminating in a sharp front edge, which is configured to break the soil as shank member 26 is moved forwardly through the soil upon operation of tractor 12.

Referring to FIG. 2, a soil moisture detection system is incorporated in tillage implement 10, for detecting soil moisture during operation of tillage implement 10. As shown in FIG. 2, the soil moisture measurement system of the invention includes a sensor or input unit 50 mounted to shin wedge 36 of shank member 26, a processor 52 in the form of a time domain reflectivity (TDR) unit, and a visual display 54 located in the operator cab area of tractor 12.

Referring to FIGS. 3-5, input unit 50 is in the form of a pair of spaced apart electrodes 56, 58, separated by an insulating block 60, secured to an insulating rear mounting member 62 and insulating top and bottom mounting members 63. A recess 64 is formed in shin wedge 36, and input unit 50 is mounted within recess 64. The various components of input unit 50 are shaped so as to correspond to the configuration of shin wedge 36, such that mounting member 62 has a width corresponding to that of shin wedge base portion 46, front electrode 56 is triangular or wedge shaped, and rear electrode 58 and insulating block 60 are trapezoidal in cross section. Front electrode 56, rear electrode 58 and insulating block 60 define cross sections which correspond to the cross section of front wedge portion 48 of shin wedge 36. Top and bottom insulating mounting members 63 also have cross sections which correspond to front wedge portion 48.

Input unit 50 may be constructed by first securing top and bottom insulating mounting members 63 to rear insulating mounting members 62, to from an insulating carrier. Alternatively, these components may be formed integrally with each other. Electrodes 56, 58 and insulating block 60 are then secured to the carrier by means of a threaded fastener, such as shown at 66 (FIG. 5), which extends into threaded passages formed in each of electrodes 56, 58 and insulating block 60. Rear insulating mounting member 62 is then secured to shin wedge base portion 46 using threaded fasteners 68 which extend into threaded passages formed in mounting member 62. A groove 69 is formed in the rear surface of shin wedge base portion 46, and a cable 70 is received within groove 69. Cable 70 includes a pair of lead wires, one of which is electrically connected to the electrode 56 and the other of which is electrically connected to electrode 58.

In operation, the soil moisture measurement system of the present invention functions as follows to measure soil moisture during operation of implement 10. The operator first lowers tillage implement 10 to engage wheels 18 with the ground, which functions to position soil penetrating portion 30 of shank member 26 below the surface of the soil. Input unit 50 is thus positioned beneath the soil surface. The operator activates processor TDR unit 52, which functions to send electrical pulses to and receive electrical pulses from electrodes 56, 58 through the wires contained within cable 70. As tractor 12 is operated to move shank member 26 through the soil, TDR unit 52 functions in a known manner to calculate volumetric soil moisture based on the time delay between pulse emission and reception between electrodes 56, 58. TDR unit 52 then outputs a visual display of volumetric soil moisture to display 54, which can be viewed by the operator. The operator can then employ a conventional operator control 72 to adjust the depth of shank member soil penetrating portion 30 using a conventional depth adjustment system 74 associated with tillage implement 10, e.g. a screw-type adjustment or a hydraulic cylinder or the like interposed between frame 16 and wheel support members 20 to move frame 16 upwardly or downwardly relative to the ground. This ensures that tillage implement 10 functions to till the soil to an appropriate depth which will create optimal conditions when the soil is seeded, and also functions to optimize fuel consumption by enabling the operator to position shank member 26 at an optimal depth.

FIG. 6 illustrates an alternative input unit 80 mounted to shin wedge 36. In this embodiment, input unit 80 is mounted within a recess formed in shin wedge base portion 46. In this configuration, input unit 80 is in the trailing portion of shin wedge 36, and does not function as a part of the leading portion of shin wedge 36 which breaks the soil as shank member 26 is moved forwardly. Input unit 80 includes an insulating block or carrier 81 mounted within a recess formed in shin wedge base portion 46, and spaced electrodes 82 are mounted within recesses formed in carrier 81. This configuration of input unit 80 may extend the life of the components of input unit 80 over that illustrated in FIGS. 1-5, while still providing sufficient contact of the electrodes of input unit 80 with the soil so as to provide accurate soil moisture input signals.

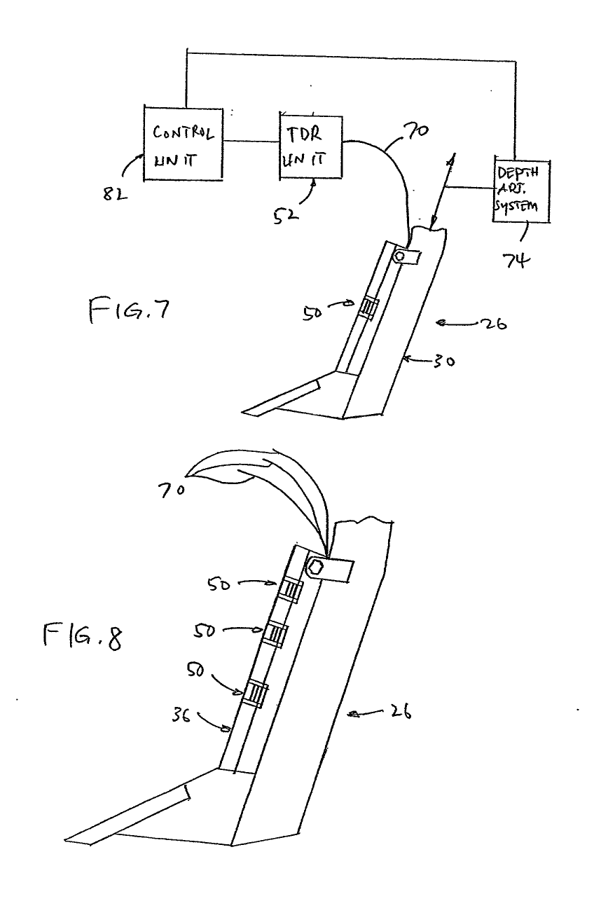

FIG. 7 illustrates an alternative embodiment to that illustrated in FIG. 2, providing automatic depth adjustment in response to soil moisture measurements. In this version, processor 52 is interconnected with a control unit 82, which in turn is connected to depth adjustment system 74. Control unit 82 is responsive to soil moisture inputs provided by processor 52, and automatically controls the depth of implement shank members 26 to a desired depth according to the soil moisture conditions and a predetermined optimal tillage depth.

FIG. 8 illustrates an alternative embodiment, in which a series of input units 50 are mounted along the length of shin wedge 36. An input cable 70 is connected to each input unit 50 in the same manner as described above, to provide soil moisture measurements at known spaced apart depths. This information can be employed to provide a soil moisture profile, to provide a more accurate soil moisture measurement than can be attained utilizing a single input unit 50 as described previously.

Representatively, TDR unit 52 may be a time domain reflectivity unit such as is available from Tektronix under its Model No. TDS3000, e.g. a 1503C general purpose TDR unit or a 1502C ultra-high resolution TDR unit, although it is understood that any other satisfactory system may be employed.

While the invention has been shown and described in relation to detecting soil density utilizing a time domain reflectivity method, it is contemplated that any other satisfactory type of soil moisture measurement system may be employed. However, it has been found that a TDR-type measurement system provides accurate soil moisture readings on the fly, requiring little or no adaptation of the TDR unit software.

In addition, while the soil moisture measurement system of the invention has been described with respect to a tillage-type implement, it is understood that the soil moisture measurement system may be incorporated in any other type of implement which penetrates the soil during operation and which benefits from soil moisture measurements for depth control. For example, a soil moisture detector may be incorporated in a grain drill for insuring that seeds are planted at a proper depth according to soil moisture conditions. Further, while the soil moisture input unit has been shown and described as being mounted to a working portion of implement 10, it is understood that the input unit may also be mounted to a separate, non-working (but soil penetrating) member associated with an implement.

Various alternatives and embodiments are contemplated as being within the scope of the following claims particularly pointing out and distinctly claiming the subject matter regarded as the invention.

We claim:

1. A mobile agricultural device, comprising:
one or more soil penetrating members;
a lifting and lowering arrangement interconnected with at least one of the soil penetrating members, wherein the lifting and lowering arrangement is operable to position at least a soil penetrating portion of the soil penetrating member below the surface of the soil; and
a soil moisture measurement system for measuring soil moisture during movement of the mobile agricultural device, wherein the soil moisture measurement system includes a soil moisture input arrangement carried by the soil penetrating portion of the soil penetrating member, wherein the soil moisture input arrangement is operable to provide inputs indicative of soil moisture during movement of the soil penetrating member through the soil.

2. The mobile agricultural device of claim 1, wherein the soil moisture measurement system includes a processor responsive to the inputs provided by the soil moisture input arrangement for calculating soil moisture.

3. The mobile agricultural device of claim 2, further comprising an operator cab, wherein the processor is interconnected with a visual display located within the operator cab for providing an operator of the mobile agricultural device with a visual indication of soil moisture during movement of the mobile agricultural device.

4. The mobile agricultural device of claim 2, further comprising a control arrangement interconnected with the processor and the lifting and lowering arrangement for altering the depth of the soil penetrating portion of the soil penetrating member in response to the soil moisture measurements.

5. The mobile agricultural device of claim 2, wherein the soil moisture input arrangement comprises a pair of spaced apart leads and wherein the processor comprises a time domain reflectivity unit interconnected with the leads for measuring soil moisture.

6. The mobile agricultural device of claim 2, wherein the soil penetrating member comprises a first portion interconnected with the lifting and lowering arrangement and a second portion releasably engaged with the first portion, and wherein the soil moisture input arrangement is interconnected with the second portion of the soil penetrating member.

7. The mobile agricultural device of claim 6, wherein the second portion of the soil penetrating member includes a recess and wherein the soil moisture input arrangement includes a pair of spaced apart input members mounted within the recess.

8. The mobile agricultural device of claim 2, wherein the soil moisture input arrangement includes a pair of spaced apart input members, and wherein each input member defines at least one surface which contacts the soil as the soil penetrating member is moved through the soil.

9. The mobile agricultural device of claim 8, wherein each input member is shaped so as to match at least a portion of a cross section defined by the soil penetrating portion of the soil penetrating member and includes a pair of surfaces that are configured to contact the soil.

10. In a mobile agricultural device having one or more soil penetrating members adapted for movement through the soil, the improvement comprising a soil moisture measuring arrangement associated with at least one of the soil penetrating members, wherein the soil moisture measuring arrangement is constructed and arranged to measure soil moisture below the soil surface during movement of the mobile agricultural device.

11. The improvement of claim 10, wherein the mobile agricultural device includes a wheeled vehicle and wherein the soil penetrating member is carried by an implement adapted to be mounted to the wheeled vehicle.

12. The improvement of claim 11, wherein the implement includes a lifting and lowering arrangement interconnected with the soil penetrating member for positioning at least a soil penetrating portion of the soil penetrating member into the soil, and wherein the soil moisture measuring arrangement includes a soil moisture input arrangement associated with the soil penetrating portion of the soil penetrating member and configured to contact the soil upon movement of the soil penetrating member through the soil.

13. The improvement of claim 12, wherein the soil moisture input arrangement includes a pair of spaced apart electrodes carried by the soil penetrating portion of the soil penetrating member and wherein the soil moisture measuring arrangement comprises a time domain reflectivity system interconnected with the leads for detecting soil moisture in response to inputs provided by the spaced apart electrodes.

14. The improvement of claim 12, wherein the lifting and lowering arrangement is interconnected with the soil moisture measuring arrangement for adjusting the depth of the soil penetrating portion of the soil penetrating member in response to soil moisture measured by the soil moisture measuring arrangement.

15. A method of measuring soil moisture, comprising the steps of:
providing a mobile agricultural device having one or more soil penetrating members, wherein at least one of the soil penetrating members includes a soil moisture input arrangement;
positioning at least a portion of the soil penetrating member, including the soil moisture input arrangement, into the soil;
moving the mobile agricultural device relative to the soil; and
measuring the soil moisture using inputs from the soil moisture input arrangement during movement of the mobile agricultural device.

16. The method of claim 15, wherein the soil moisture input is secured to the soil penetrating member so as to provide contact of the soil moisture input arrangement with the soil when a soil penetrating portion of the soil penetrating member is positioned into the soil.

17. The method of claim 16, wherein the step of measuring the soil moisture is carried out using time domain reflectivity inputs from the soil moisture input arrangement.

18. The method of claim 16, wherein the soil moisture input arrangement is secured to the soil penetrating portion of one of the soil penetrating members by forming a recess in the soil penetrating portion of the soil penetrating member and engaging the soil moisture input arrangement within the recess.

19. The method of claim 18, wherein the soil moisture input arrangement comprises a pair of spaced apart electrodes and an insulating member there between, and wherein the step of engaging the soil moisture input arrangement within the recess is carried out by securing the electrodes and the insulating member within the recess.

20. The method of claim 19, wherein the electrodes and the insulating member are engaged within the recess by connecting the electrodes and the insulating member together to form a soil moisture input subassembly which is engaged as a unit within the recess in the soil penetrating portion of the soil penetrating member.

21. The method of claim 15, wherein the step of measuring the soil moisture using inputs from the soil moisture input arrangement is carried out by a processor interconnected with the soil moisture input arrangement for processing the inputs to calculate soil moisture.
